(19) United States
(12) Patent Application Publication
(10) Pub. No.: US 2026/0122950 A1
(43) Pub. Date: Apr. 30, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: En-Shuo LIN, New Taipei City (TW); Chuan-Wei TSOU, Hsinchu City (TW); Wei WANG, Taipei City (TW); Chia-Wei CHEN, Hsinchu (TW); Yao-Chung CHANG, Hsinchu County (TW); Chun-Lin TSAI, Hsinchu (TW)

(73) Assignee: TAIWAN SEMICONDUCTOR MANUFACTURING COMPANY, LTD., Hsinchu (TW)

(21) Appl. No.: 18/927,748

(22) Filed: Oct. 25, 2024

(51) Int. Cl. H01L 29/778; H01L 29/20; H01L 29/40; H01L 29/423; H01L 29/66

(52) U.S. Cl. CPC H10D 30/475; H10D 30/015; H10D 62/8503; H10D 64/01; H10D 64/111; H10D 64/411

(57) ABSTRACT

A semiconductor device includes a substrate, a channel layer over the substrate, a gate structure over the channel layer, a source electrode and a drain electrode on opposite sides of the gate structure and electrically connected with the channel layer, and a field plate between the gate structure and the drain electrode. The field plate vertically overlaps an edge of the gate structure.

### BACKGROUND

The semiconductor integrated circuit (IC) industry has experienced exponential growth. Technological advances in IC materials and design have produced generations of ICs where each generation has smaller and more complex circuits than the previous generation. In semiconductor technology, gallium nitride (GaN) as the third generation of wide band gap semiconductor material, has characteristics of large band gap, high breakdown voltage, the two-dimensional electron gas has large electron velocity at high concentrations. Gallium nitride is used to form various integrated circuit devices, such as high power field-effect transistors, metal insulator semiconductor field effect transistors (MISFETs), high frequency transistors, and high electron mobility transistors (HEMTs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 8 are cross-sectional views of various steps of a method of fabricating a semiconductor device in accordance of some embodiments of the disclosure.

FIG. 9 is a top view of a semiconductor device in accordance of some embodiments of the disclosure.

FIGS. 10 and 11 are simulation results of semiconductor devices in accordance of some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Gallium nitride HEMTs on silicon substrates are used as power switching transistors for voltage converter applications. Compared to silicon power transistors, gallium nitride HEMTs feature low on-state resistances, and low switching losses due to wide bandgap properties.

Enhancement-mode aluminum gallium nitride/gallium nitride high electron mobility transistors (E-HEMTs) are used in power circuit applications. The E-HEMT includes a field plate design to modulate electric fields in a channel.

High voltages in a junction between the channel and drift region lead to low breakdown voltages. Electric field in the junction can be reduced by incorporating a very low doping in the drift region. Since this increases the resistance, other solutions such as decreasing a peak of the electric field is used. The solution is also known as reduced surface field (RESURF) technique. The RESURF technique can use a field plate structure to lower a gate-to-drain capacitance (Cgd) and to increase power efficiency.

However, as device continuously scaling down, the shorter gate-to-drain length (Lgd) will cause high Cgd and therefore high E-field around the gate edge. The present disclosure provides a HEMT device by forming a field plate that covers an edge of the gate structure. Accordingly, the electric field around the gate edge may be reduced, which will further reduce the gate-to-drain capacitance (Cgd). With such configuration, the device performance may be improved.

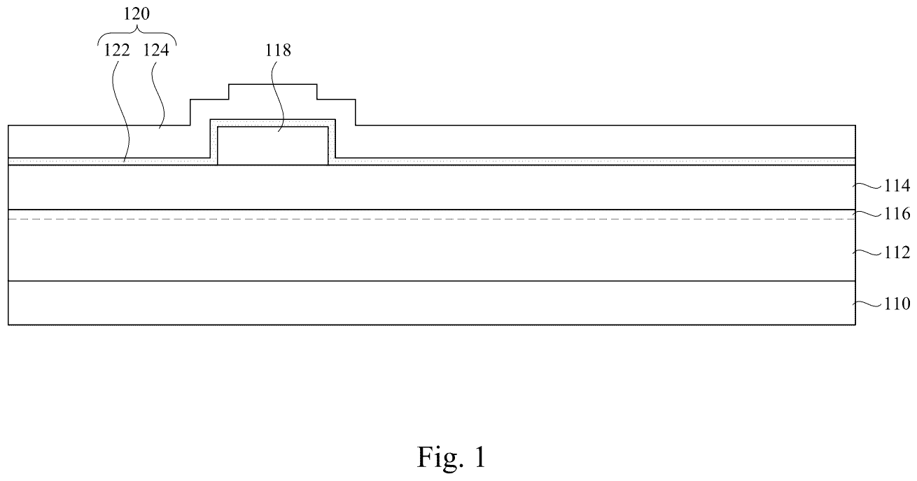

FIGS. 1 to 8 are cross-sectional views of various steps of a method of fabricating a semiconductor device in accordance of some embodiments of the disclosure. Although the method of FIGS. 1 to 8 is described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 110. A channel layer 112 is formed over the substrate 110, and a donor-supply layer 114 is formed over the channel layer 112. The substrate 110 is a semiconductor substrate. In some embodiments, the semiconductor substrate is made of, for example, silicon; a compound semiconductor, such as silicon carbide, indium arsenide, or indium phosphide; or an alloy semiconductor, such as silicon germanium carbide, gallium arsenic phosphide, or gallium indium phosphide. The substrate 110 may also include various doped regions, dielectric features, or multilevel interconnects in the semiconductor substrate.

The channel layer 112 and the donor-supply layer 114 may be epitaxial layers, such as semiconductive compounds made from the III-V groups in the periodic table of elements. As a result, the channel layer 112 and the donor-supply layer 114 may also be referred to as III-V compound layers. However, the channel layer 112 and the donor-supply layer 114 may be different from each other in composition. In some embodiments, the channel layer 112 may be made of gallium nitride (GaN) layer. In such embodiments, the channel layer 112 can be epitaxially grown by a number of processes including, but not limited to, metal organic chemical vapor deposition (MOCVD), also known as metal organic vapor phase epitaxy (MOVPE), using appropriate nitrogen and gallium containing precursors. For example, exemplary gallium containing precursors are trimethlgallium (TMG), triethylgallium (TEG) or other suitable chemical precursors. Exemplary nitrogen precursors include, but are not limited to, phenyl hydrazine, dimethylhydrazine, tertiarybutylamine, ammonia, or other suitable chemical precursors.

In some embodiments, the donor-supply layer 114 may be made of aluminum gallium nitride (AlGaN) layer. In such embodiments, the donor-supply layer 114 can be epitaxially grown by MOCVD using appropriate aluminum, nitrogen and gallium precursors. The aluminum precursor includes trimethylaluminum (TMA), triethylaluminum (TEA), or suitable chemical precursors. Exemplary gallium containing precursors are trimethlgallium (TMG), triethylgallium (TEG) or other suitable chemical precursors. Exemplary nitrogen precursors include, but are not limited to, phenyl hydrazine, dimethylhydrazine, tertiarybutylamine, ammonia, or other suitable chemical precursors. The donor-supply layer 114 can also be referred to as a barrier layer. The Channel layer 112 and the donor-supply layer 114 directly contact each other. A transition layer, usually present between the substrate 110 and the channel layer 112, is not shown.

Different materials formed on the semiconductor substrate 110 causes the layers to have different band gaps. A band gap discontinuity exists between the donor-supply layer 114 and the channel layer 112. The electrons from a piezoelectric effect in the donor-supply layer 114 drop into the channel layer 112, creating a very thin layer of highly mobile conducting electrons in the channel layer 112. This thin layer is referred to as a two-dimensional electron gas (2-DEG), forming a carrier channel 116. The thin layer of 2-DEG is located near interface S8 of the donor-supply layer 114 and the channel layer 112. Thus, the carrier channel 116 has high electron mobility because the channel layer 112 is undoped or unintentionally doped, and electrons can move freely without collision or substantially reduced collision with impurities.

A doped epitaxial layer 118 is formed over the donor-supply layer 114. In some embodiments, the doped epitaxial layer 118 may also be referred to as a gate structure. In some embodiments, the doped epitaxial layer 118 may be a gallium nitride (GaN) layer doped with P-type impurities or N-type impurities. Possible P-type impurities may include boron (B), gallium (Ga), indium (In), aluminium (Al), or the like. Possible N-type impurities may include phosphorus (P), arsenic (As), or antimony (Sb), or the like. In the present disclosure, the doped epitaxial layer 118 may be a GaN layer doped with P-type impurities, and can also be referred to as a P—GaN layer. The doped epitaxial layer 118 may be formed by, for example, depositing an epitaxial layer over the donor-supply layer 114. An ion implantation process is performed to dope the epitaxial layer. A mask layer, such as a photoresist layer is then formed on the epitaxial layer, and the mask layer is patterned by a lithography process to form a plurality of openings. Then, an etching process is performed to remove portions of the epitaxial layer through the openings of the mask layer to define the doped epitaxial layer 118.

A dielectric structure 120 is formed over the substrate 110 and covering the doped epitaxial layer 118. In some embodiments, the dielectric structure 120 may be a multi-layer dielectric structure, which includes a first dielectric layer 122 and a second dielectric layer 124 over the first dielectric layer 122. The first dielectric layer 122 and the second dielectric layer 124 may be made of different dielectric materials. For example, the first dielectric layer 122 may be made of nitride, such as aluminum nitride (AlN) or silicon nitride (SiN), and the second dielectric layer 124 may be made of oxide, such as silicon oxide (SiO₂). The first dielectric layer 122 and the second dielectric layer 124 can be formed by a deposition process, such as an ALD process, a CVD process, or a PVD process.

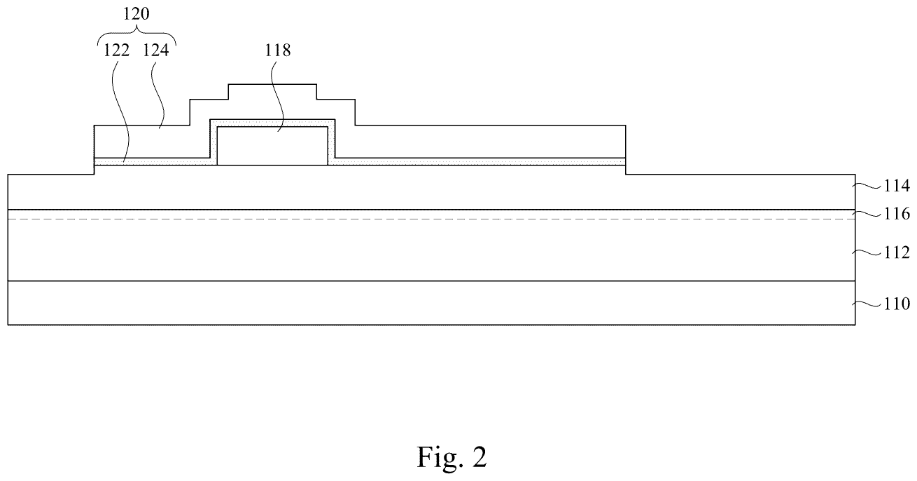

Reference is made to FIG. 2. The dielectric structure 120 is patterned to expose portions of the donor-supply layer 114. In some embodiments, a patterned photoresist (not shown) is formed over the substrate 110 and covering portions of the dielectric structure 120, while leaving unwanted portions of the dielectric structure 120 exposed. An etching process is performed, through the patterned photoresist, to remove the unwanted portions of the dielectric structure 120, so as to expose the donor-supply layer 114. After the etching process is complete, the patterned photoresist is removed. In some embodiments, the donor-supply layer 114 may also be etched during etching the dielectric structure 120. Accordingly, top surfaces of the exposed portions of the donor-supply layer 114 may be lower than top surfaces of the portion of the donor-supply layer 114 protected by the dielectric structure 120.

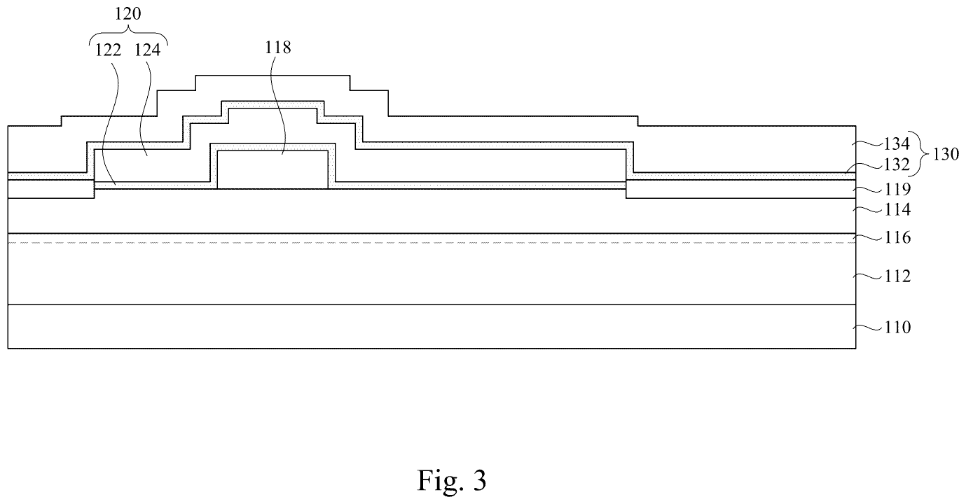

Reference is made to FIG. 3. An epitaxial layer 119 is regrown from the exposed surfaces of the donor-supply layer 114. In some embodiments, the epitaxial layer 119 may be made of a same material as the donor-supply layer 114. For example, the donor-supply layer 114 and the epitaxial layer 119 may be made of aluminum gallium nitride (AlGaN). However, the donor-supply layer 114 and the epitaxial layer 119 may be made of different materials in other embodiments. In some embodiments, the epitaxial layer 119 can be formed using a selective epitaxial growth (SEG) process, such that the epitaxial material of the epitaxial layer 119 is selectively formed on the epitaxial material of the exposed donor-supply layer 114. That is, the material of the epitaxial layer 119 may include a higher growth rate on the donor-supply layer 114 than on the dielectric structure 120. In some embodiments, the top surface of the epitaxial layer 119 may be higher than the topmost surface of the epitaxial layer 119 and the bottom surface of the epitaxial layer 119 may be lower than the topmost surface of the epitaxial layer 119.

A dielectric structure 130 is formed over the substrate 110 and covering the epitaxial layer 119 and the dielectric structure 120. In some embodiments, the dielectric structure 130 may laterally surrounds the dielectric structure 120. In some embodiments, the dielectric structure 130 may be a multi-layer dielectric structure, which includes a first dielectric layer 132 and a second dielectric layer 134 over the first dielectric layer 132. The first dielectric layer 132 and the second dielectric layer 134 may be made of different dielectric materials. For example, the first dielectric layer 132 may be made of nitride, such as aluminum nitride (AlN), and the second dielectric layer 134 may be made of nitride, such as silicon nitride (SiN). The first dielectric layer 132 and the second dielectric layer 134 can be formed by a deposition process, such as an ALD process, a CVD process, or a PVD process.

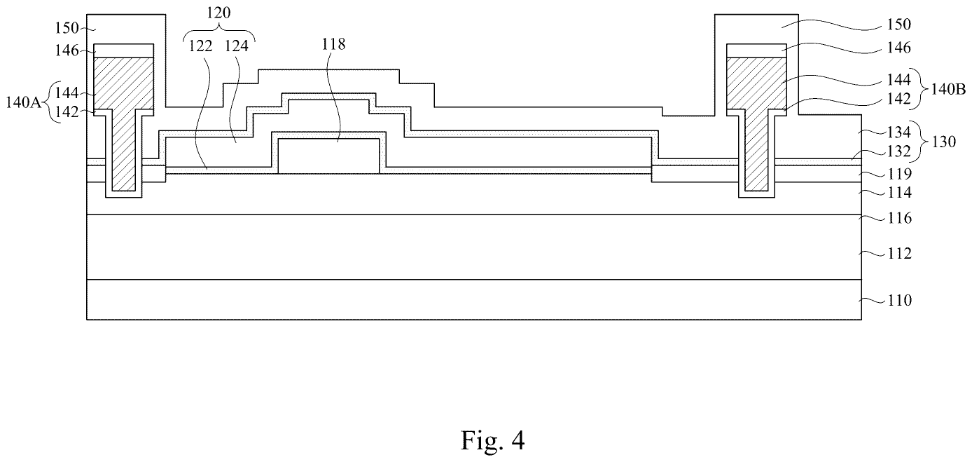

Reference is made to FIG. 4. Source/drain electrodes 140A and 140B are formed extending through the dielectric structure 130 and the epitaxial layer 119, and stopping at the donor-supply layer 114, and therefore electrically connected with the channel layer 112. In some embodiments, the source/drain electrodes 140A can serve as the source region of a semiconductor device, and the source/drain electrodes 140B can serve as the drain region of the semiconductor device. The doped epitaxial layer 118 is closer to the source/drain electrode 140A than to the source/drain electrode 140B. That is, a distance between the doped epitaxial layer 118 and the source/drain electrode 140A is less than a distance between the doped epitaxial layer 118 and the source/drain electrode 140B.

Each of the source/drain electrodes 140A and 140B may include a first conductive layer 142 and a second conductive layer 144 over the first conductive layer 142. In some embodiments, the first conductive layer 142 may be an ohmic metal layer. Exemplary ohmic metal may include, but are not limited to, Ta, TaN, Pd, W, WSi₂, Ti, Al, TiN, AlCu, AlSiCu and Cu. In some embodiments, the second conductive layer 144 may be an anti-reflective coating (ARC) layer. Exemplary ARC layer may include TiN or other suitable material. Also, an etch stop layer 146 is formed on the second conductive layer 144. The etch stop layer 146 can be made of oxide (SiO₂), nitride (SiN), or other suitable material. In some embodiments, the etch stop layer 146 is deposited to a thickness ranging from about 400 to 600 angstrom.

The source/drain electrodes 140A and 140B can be formed by, for example, patterning dielectric structure 130 and the epitaxial layer 119 to define a plurality of openings in the dielectric structure 130 and the epitaxial layer 119 that expose the donor-supply layer 114. The first conductive layer 142 is deposited over the dielectric structure 130 and filling the openings. The deposition process can be sputter deposition, evaporation or chemical vapor deposition (CVD). Post deposition annealing of the first conductive layer 142 is then performed to induce any desirable reactions between the ohmic metal and the donor-supply layer 114. In some embodiments, the first conductive layer 142 is formed by rapid thermal annealing (RTA) at an annealing temperature ranging from approximately 800° C. to approximately 900° C. Then, the second conductive layer 144 is deposited over the first conductive layer 142 using suitable deposition process, such as sputter deposition, evaporation or CVD. The etch stop layer 146 is then formed over the second conductive layer 144 using suitable deposition process, such as ALD or CVD. The first conductive layer 142, the second conductive layer 144, and the etch stop layer 146 are patterned to define the source/drain electrodes 140A and 140B. As a result, the source/drain electrodes 140A and 140B are electrically connected to the donor-supply layer 114. In some embodiments, the source/drain electrodes 140A and 140B are in contact with the donor-supply layer 114.

Once the source/drain electrodes 140A and 140B and the etch stop layer 146 are formed, protective layers 150 are formed lining the respective source/drain electrodes 140A and 140B. For example, the protective layers 150 may be in contact with opposite sidewalls of the respective source/drain electrodes 140A and 140B, and may extend to top surface of the respective etch stop layers 146. In some embodiments, the protective layers 150 may be made of suitable dielectric material, such as silicon nitride (SiN). The protective layers 150 may be formed by, for example, depositing a dielectric layer blanket over the substrate 100, and then patterning the dielectric layer.

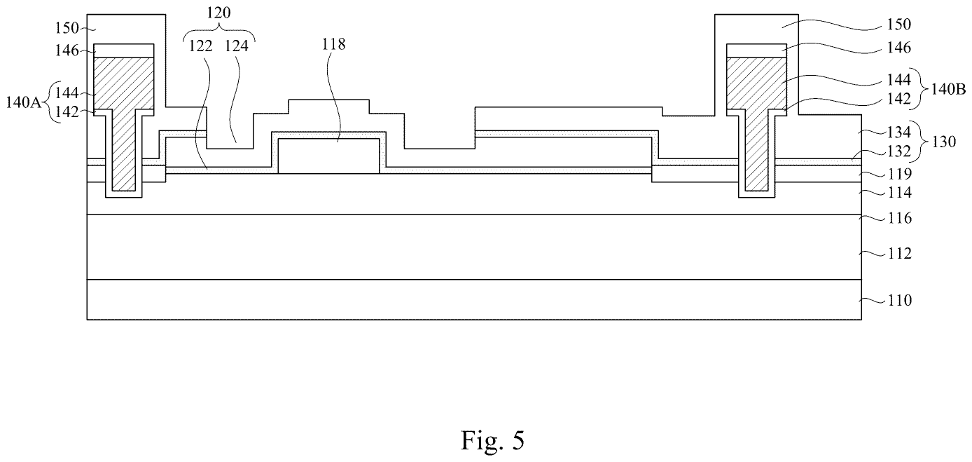

Reference is made to FIG. 5. Portions of the dielectric structure 130 are removed to expose the dielectric structure 120. Specifically, the second dielectric layer 124 of the dielectric structure 120 may be exposed by removing the portions of the dielectric structure 130. In some embodiments, the portions of the dielectric structure 130 are removed to expose portions of the dielectric structure 120 that is vertically above the doped epitaxial layer 118. In some embodiments, the portions of the dielectric structure 130 may be removed by, for example, forming a patterned photoresist (not shown) having an opening exposing unwanted portions of the dielectric structure 130, and then performing an etching process to remove the unwanted portions of the dielectric structure 130 until the dielectric structure 120 is exposed.

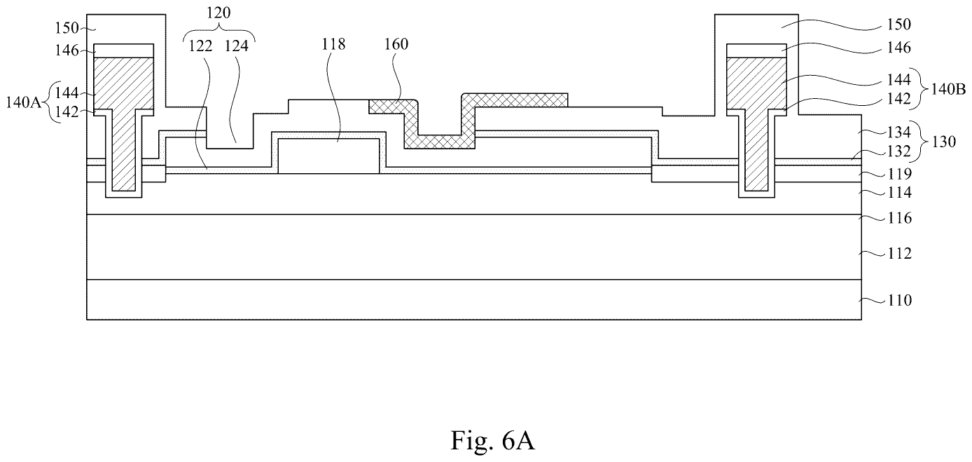

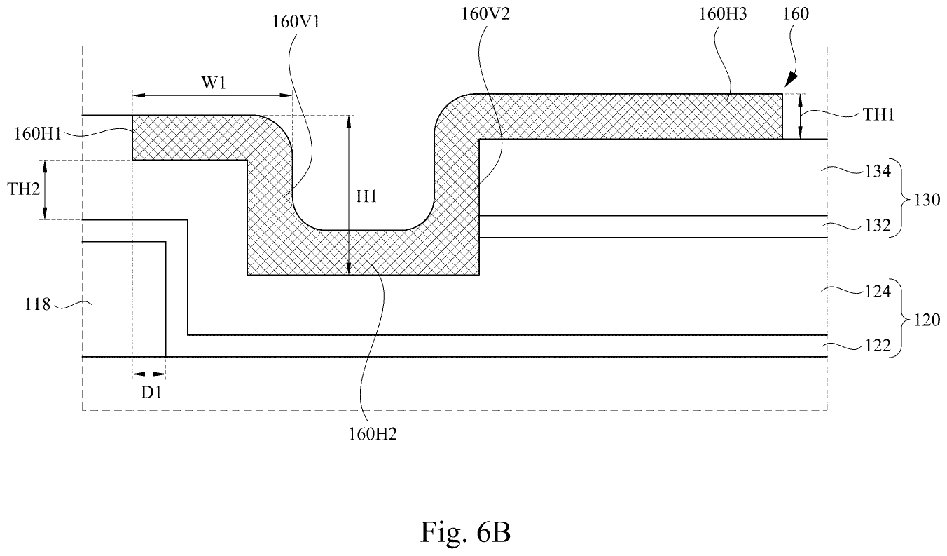

Reference is made to FIGS. 6A and 6B, in which FIG. 6B is an enlarged view of FIG. 6A. A field plate 160 is formed over the dielectric structures 120 and 130. In some embodiments, the field plate 160 is formed between the doped epitaxial layer 118 and the source/drain electrode 140B along the horizontal direction. The processes of forming the field plate 160 include forming a field plate metal layer over the dielectric structures 120 and 130 and patterning the field plate metal layer. The field plate metal layer can be formed by a deposition process, such as an ALD process, a CVD process, or a PVD process. The patterning process includes performing one or more etching processes. The field plate 160 can be made of titanium nitride (TiN), aluminum copper (AlCu), aluminum silicon copper (AlSiCu), titanium (Ti), tantalum (TaN), titanium tungsten (TiW), copper (Cu), or other suitable metal.

The etch stop layer 146 and the protective layers 150 may be utilized to protect the underlying source/drain electrodes 140A and 140B from being etched during the process of etching the field plate 160. As a result, the profiles of the source/drain electrodes 140A and 140B may be maintained, and the issue of metal loss of the source/drain electrodes 140A and 140B during the process of defining the field plate 160 can be prevented.

As shown in FIG. 6B, the field plate 160 includes horizontal portions 160H1, 160H2, and 160H3 extending along the horizontal direction, and vertical portions 160V1 and 160V extending along the vertical direction, in which the vertical portion 160V1 connects the horizontal portions 160H1 and 160H2, and the vertical portion 160V2 connects the horizontal portions 160H2 and 160H3. The horizontal portion 160H1 extends along a lateral surface of the second dielectric layer 124 of the dielectric structure 120. The vertical portion 160V1 extends along a vertical surface of the second dielectric layer 124 of the dielectric structure 120. The horizontal portion 160H2 extends along a lateral surface of the second dielectric layer 124 of the dielectric structure 120. The vertical portion 160V2 extends along a vertical surface of the second dielectric layer 124 of the dielectric structure 120, a vertical surface of the first dielectric layer 132 of the dielectric structure 130, and a vertical surface of the second dielectric layer 134 of the dielectric structure 130. The horizontal portion 160H3 extends along a lateral surface of the second dielectric layer 134 of the dielectric structure 130.

In some embodiments, the horizontal portion 160H1 is at a position that is higher than the horizontal portion 160H2 and is lower than the horizontal portion 160H3. In some embodiments, the vertical portion 160V1 may include a vertical height that is less than the vertical height of the vertical portion 160V2.

As mentioned above, the horizontal portion 160H1 extends along a lateral surface of the second dielectric layer 124 of the dielectric structure 120. More specifically, the horizontal portion 160H1 may extend to a position that is vertically above a portion of the doped epitaxial layer 118. That is, a portion of the horizontal portion 160H1 may vertically overlap the doped epitaxial layer 118 by a lateral distance D1. In some embodiments, the lateral distance D1 is a non-zero distance and is in a range from about 80 nm to about 120 nm, such as about 100 nm.

The present disclosure provides a HEMT device by forming a field plate 160 that covers an edge of the gate structure (e.g., the doped epitaxial layer 118). Accordingly, the electric field around the gate structure may be reduced, which will further reduce the capacitance between gate-to-drain (Cgd). With such configuration, the device performance may be improved.

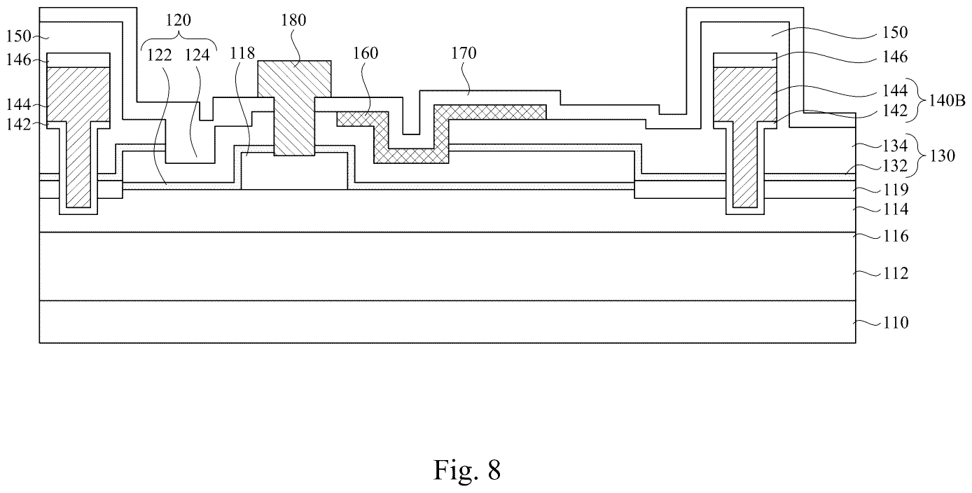

In some embodiments, the field plate 160 may include a thickness TH1 in a range from about 1000 angstrom to about 2000 angstrom. In some embodiments, the horizontal portion 160H1 may include a lateral width W1 in a range from about 0.35 μm to about 0.4 μm. If the lateral width W1 is too large, the horizontal portion 160H1 may be too close to the following formed gate electrode (e.g., gate electrode 180 of FIG. 8) and may potentially cause unwanted short circuit with the gate electrode. If the lateral width W1 is too small, the horizontal portion 160H1 may not be enough to reduce the electric field around the gate structure. In some embodiments, the vertical portion 160V1 may include a vertical height H1 in a range from about 900 angstrom to about 1100 angstrom, such as about 1000 angstrom. In some embodiments, the second dielectric layer 124 of the dielectric structure 120 may include a portion that is vertically between the horizontal portion 160H1 of the field plate 160 and the doped epitaxial layer 118, in which such portion may include a thickness TH2 in a range from about 1800 angstrom to about 2200 angstrom, such as about 2000 angstrom.

In some embodiments, due to the nature of deposition process, the field plate 160 may include rounding corners at the corners of the dielectric structures 120 and 130. For example, the horizontal portion 160H1 and the vertical portion 160V1 may form a rounding corner, and the horizontal portion 160H3 and the vertical portion 160V2 may form a rounding corner. The rounding corners may be helpful to reduce corona discharge effect around the gate structure, and therefore reduce the electric field around the gate structure.

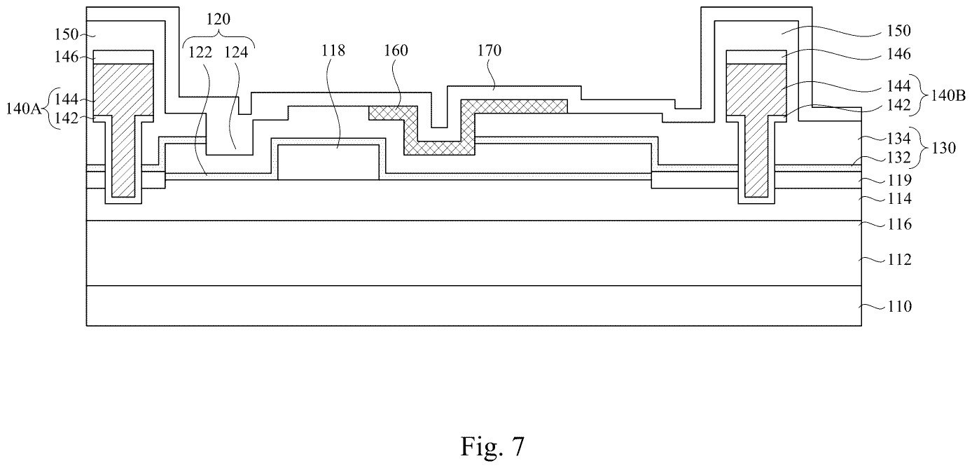

Reference is made to FIG. 7. Once the field plate 160 is formed, a dielectric layer 170 is formed over the substrate 110 and covering the field plate 160. In greater detail, and may also extend along the surfaces of the horizontal portions 160H1, 160H2, and 160H3, and vertical portions 160V1 and 160V of the field plate 160. The dielectric layer 170 may also extend along the surfaces of the dielectric structures 120 and 130 and the protective layers 150. The dielectric layer 170 can be made of silicon oxide, silicon nitride, silicon oxynitride, silicon carbide, low-dielectric constant dielectric material or a combination thereof. The dielectric layer 170 can be formed by a deposition process, such as an ALD process, a CVD process, or a PVD process. The thickness of the dielectric layer 170 is in a range from about 500 angstrom to about 5000 angstrom, such as about 1000 angstrom.

Reference is made to FIG. 8. A gate electrode 180 is formed extending through the dielectric layer 170 and the dielectric structure 120 and in contact with the doped epitaxial layer 118. In some embodiments, the gate electrode 180 may include a refractory metal or its compounds, such as tungsten (W), titanium nitride (TiN) and tantalum (Ta). Other metals such as nickel (Ni) and gold (Au) may also be employed for the gate electrode 180. The gate electrode 180 may be formed by, for example, patterning the dielectric layer 170 and the dielectric structure 120 to form an opening exposing the doped epitaxial layer 118, filling a conductive material in the opening, and then patterning the conductive material. In some embodiments, the gate electrode 180 may be laterally spaced apart from the field plate 160. That is, the gate electrode 180 does not vertically overlap with field plate 160. Alternatively, an edge of the gate electrode 180 closest to the field plate 160 is laterally spaced apart from an edge of the field plate 160 closest to the gate electrode 180. In some embodiments, the topmost surface of the gate electrode 180 is higher than the topmost surface of the field plate 160.

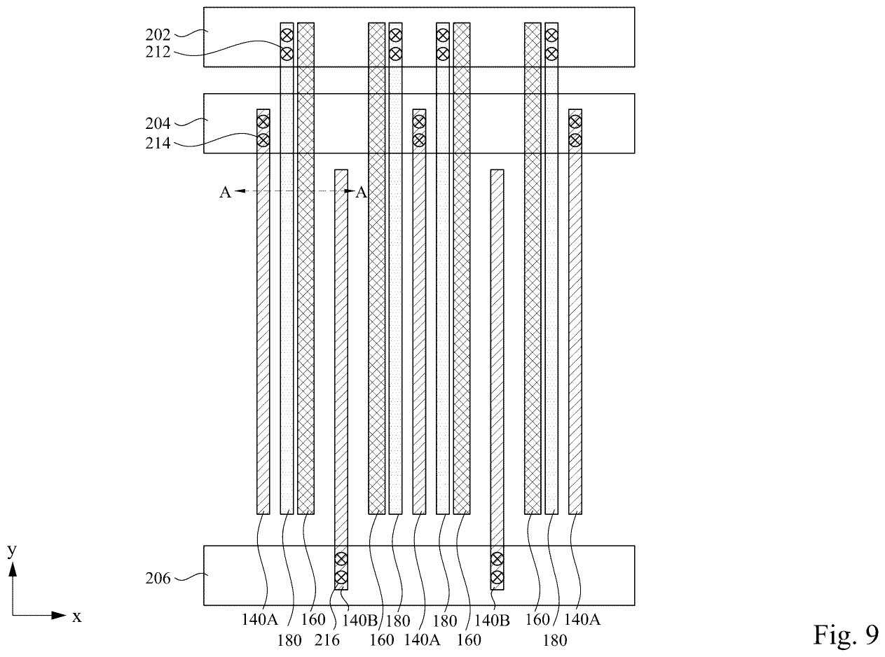

FIG. 9 is a top view of a semiconductor device in accordance of some embodiments of the disclosure. Specifically, the cross-sectional view of FIG. 8 may be taken along line A-A from the top view of FIG. 9. Some elements of FIG. 9 have been discussed above with respect to FIGS. 1 to 8, such elements are labeled the same, and relevant details will not be repeated for brevity.

The semiconductor device shown in FIG. 9 includes source/drain electrodes 140A, 140B, gate electrodes 180, and field plates 160 arranged along the X-direction. In greater detail, the each of the source/drain electrodes 140A, 140B, gate electrodes 180, and field plates 160 may include a lengthwise direction along the Y-direction that is substantially perpendicular to the X-direction.

The semiconductor device shown in FIG. 9 further includes a gate pad 202, a source pad 204, and a drain pad 206 arranged along the Y-direction and vertically above the source/drain electrodes 140A, 140B, gate electrodes 180, and field plates 160. In some embodiments, each of the gate pad 202, the source pad 204, and the drain pad 206 may include a lengthwise direction along the X-direction.

The gate pad 202 may be electrically connected with the gate electrodes 180 through a plurality of gate vias 212, in which the gate vias 212 may be in contact with bottom surface of the gate pad 202 and top surfaces of the respective gate electrodes 180. The source pad 204 may be electrically connected with the source/drain electrodes 140A through a plurality of source vias 214, in which the source vias 214 may be in contact with bottom surface of the source pad 204 and top surfaces of the respective source/drain electrodes 140A. The drain pad 206 may be electrically connected with the source/drain electrodes 140B through a plurality of drain vias 216, in which the drain vias 216 may be in contact with bottom surface of the drain pad 206 and top surfaces of the respective source/drain electrodes 140B.

In some embodiments, the gate pad 202, the source pad 204, the drain pad 206, the gate vias 212, the source vias 214, and the drain vias 216 may be made of suitable conductive material, such as Ti, Mo, Pt, Cr, W, Ni, Al, AlCu, AlSiCu, Cu, or other suitable material. In some embodiments, the gate vias 212, the source vias 214, and the drain vias 216 may be formed in contact with the respective gate electrodes 180 and source/drain electrodes 140A and 140B. Then, the gate pad 202, the source pad 204, the drain pad 206 may be formed in contact with the gate vias 212, the source vias 214, and the drain vias 216, respectively.

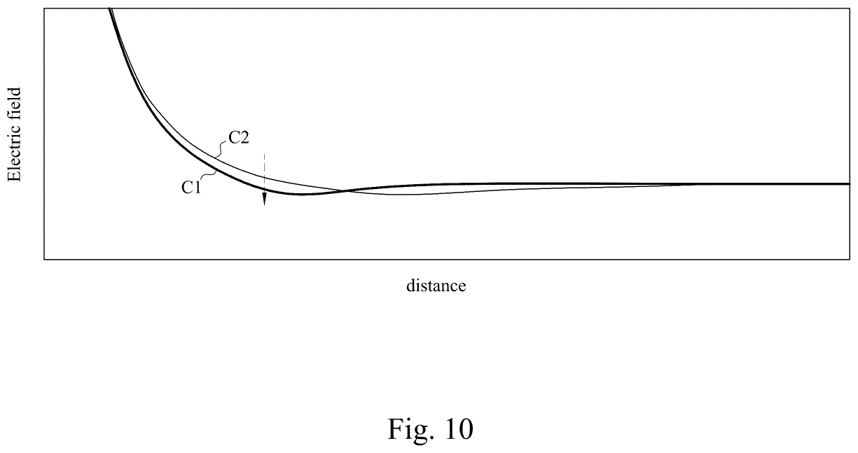

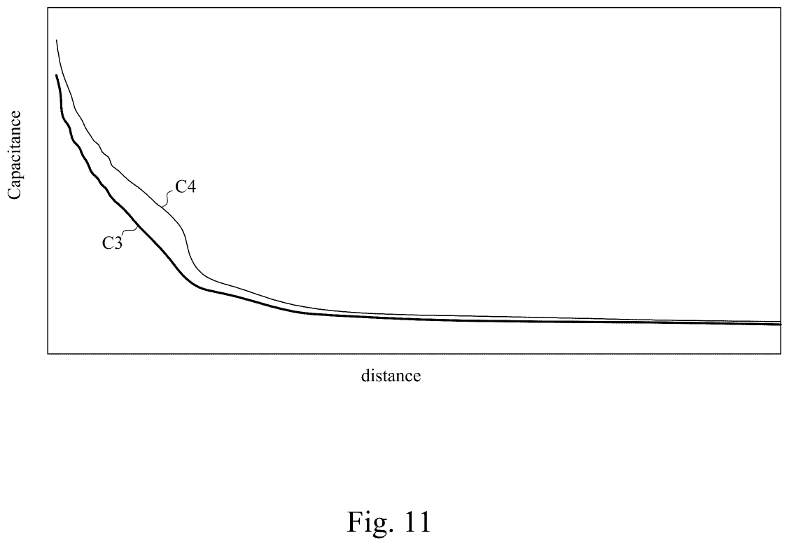

FIGS. 10 and 11 are simulation results of semiconductor devices in accordance of some embodiments of the disclosure. In greater detail, two semiconductor devices are simulated, in which one semiconductor device includes a field plate having a portion vertically overlapping the gate structure (e.g., the structure of FIG. 8), and another semiconductor device includes a field plate that does not overlap the gate structure.

FIG. 10 is a plot of electric field versus distance, in which the curve C1 is for a semiconductor device with a field plate vertically overlapping the gate structure and the curve C2 is for a semiconductor device with a field plate non-overlapping the gate structure. Comparing the curves C1 and C2, it can be seen that a lower electric field is obtained around the gate region when the field plate vertically overlaps the gate structure. In some embodiments, the electric field may be reduced by about 47% when the field plate vertically overlaps the gate structure.

FIG. 11 shows a plot of capacitance versus distance, in which the curve C3 is for a semiconductor device with a field plate vertically overlapping the gate structure and the curve C4 is for a semiconductor device with a field plate non-overlapping the gate structure. Comparing the curves C3 and C4, it can be seen that a lower capacitance is obtained around the gate region when the field plate vertically overlaps the gate structure.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a HEMT device by forming a field plate that covers an edge of the gate structure. Accordingly, the electric field around the gate structure may be reduced, which will further reduce the gate-to-drain capacitance (Cgd). With such configuration, the device performance may be improved.

In some embodiments of the present disclosure, a semiconductor device includes a substrate, a channel layer over the substrate, a gate structure over the channel layer, a source electrode and a drain electrode on opposite sides of the gate structure and electrically connected with the channel layer, and a field plate between the gate structure and the drain electrode. The field plate vertically overlaps an edge of the gate structure.

In some embodiments, the semiconductor device further includes a dielectric layer vertically between the gate structure and the field plate, wherein the field plate extends from a top surface of the dielectric layer to a sidewall of the dielectric layer.

In some embodiments, a thickness of the dielectric layer is in a range from about 1800 angstrom to about 2200 angstrom.

In some embodiments, the field plate is made of titanium nitride (TiN), aluminum copper (AlCu), aluminum silicon copper (AlSiCu), titanium (Ti), tantalum (TaN), titanium tungsten (TiW), copper (Cu).

In some embodiments, the gate structure is made of P-type gallium nitride.

In some embodiments, the semiconductor device further includes a gate electrode in contact with a top surface of the gate structure, wherein the gate electrode is laterally spaced apart from the gate structure.

In some embodiments, wherein the field plate vertically overlaps the gate structure by about 100 nm.

In some embodiments of the present disclosure, a semiconductor device includes a substrate, a channel layer over the substrate, a donor-supply layer over the channel layer, a gate structure over the channel layer, a first dielectric structure covering the gate structure, a second dielectric structure laterally surrounding the first dielectric structure, a source electrode and a drain electrode extending through the second dielectric structure and in contact with the donor-supply layer, and a field plate extending along the first dielectric structure and the second dielectric structure. The field plate extends to a position vertically above the gate structure.

In some embodiments, the field plate comprises first, second, and third horizontal portions, and first and second vertical portions, and wherein the first vertical portion connects the first horizontal portion and the second horizontal portion, and the second vertical portion connects the second horizontal portion and the third horizontal portion.

In some embodiments, the first horizontal portion extends to the position vertically above the gate structure.

In some embodiments, the first horizontal portion and the first horizontal portion forms a rounding corner.

In some embodiments, the first and second horizontal portions extend along the first dielectric structure and the third horizontal portion extends along the second dielectric structure.

In some embodiments, the first horizontal portion is at a level above the second horizontal portion and below the third horizontal portion.

In some embodiments, the semiconductor device further includes a gate electrode in contact with a top surface of the gate structure, wherein a topmost surface of the gate electrode is higher than a topmost surface of the field plate.

In some embodiments, the semiconductor device further includes an epitaxial layer between the donor-supply layer and the second dielectric structure, in which the source electrode and the drain electrode extends through the epitaxial layer.

In some embodiments of the present disclosure, a method includes forming a gate structure over a channel layer; forming a first dielectric structure covering the gate structure; forming a source electrode and a drain electrode on opposite sides of the gate structure; forming a field plate extending along the first dielectric structure, wherein the field plate vertically overlaps an edge of the gate structure; and forming a gate electrode connected with the gate structure.

In some embodiments, the method further includes forming a second dielectric structure laterally surrounding the first dielectric structure, wherein the field plate further extends to the second dielectric structure.

In some embodiments, the method further includes forming a donor-supply layer over the channel layer prior to forming the gate structure.

In some embodiments, the method further includes patterning the first dielectric structure to expose portions of the donor-supply layer; and forming an epitaxial layer over the portions of the donor-supply layer, wherein the source electrode and the drain electrode are formed extending through the epitaxial layer.

In some embodiments, the portions of the donor-supply layer are etched during patterning the first dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a channel layer over the substrate;
a gate structure over the channel layer;
a source electrode and a drain electrode on opposite sides of the gate structure and electrically connected with the channel layer; and
a field plate between the gate structure and the drain electrode, wherein the field plate vertically overlaps an edge of the gate structure.

2. The semiconductor device of claim 1, further comprising a dielectric layer vertically between the gate structure and the field plate, wherein the field plate extends from a top surface of the dielectric layer to a sidewall of the dielectric layer.

3. The semiconductor device of claim 2, wherein a thickness of the dielectric layer is in a range from about 1800 angstrom to about 2200 angstrom.

4. The semiconductor device of claim 1, wherein the field plate is made of titanium nitride (TiN), aluminum copper (AlCu), aluminum silicon copper (AlSiCu), titanium (Ti), tantalum (TaN), titanium tungsten (TiW), copper (Cu).

5. The semiconductor device of claim 1, wherein the gate structure is made of P-type gallium nitride.

6. The semiconductor device of claim 1, further comprising a gate electrode in contact with a top surface of the gate structure, wherein the gate electrode is laterally spaced apart from the gate structure.

7. The semiconductor device of claim 1, wherein the field plate vertically overlaps the gate structure by about 100 nm.

8. A semiconductor device, comprising:
a substrate;
a channel layer over the substrate;
a donor-supply layer over the channel layer;
a gate structure over the channel layer;
a first dielectric structure covering the gate structure;
a second dielectric structure laterally surrounding the first dielectric structure;
a source electrode and a drain electrode extending through the second dielectric structure and in contact with the donor-supply layer; and
a field plate extending along the first dielectric structure and the second dielectric structure, wherein the field plate extends to a position vertically above the gate structure.

9. The semiconductor device of claim 8, wherein the field plate comprises first, second, and third horizontal portions, and first and second vertical portions, and wherein the first vertical portion connects the first horizontal portion and the second horizontal portion, and the second vertical portion connects the second horizontal portion and the third horizontal portion.

10. The semiconductor device of claim 9, wherein the first horizontal portion extends to the position vertically above the gate structure.

11. The semiconductor device of claim 9, wherein the first horizontal portion and the first horizontal portion forms a rounding corner.

12. The semiconductor device of claim 9, wherein the first and second horizontal portions extend along the first dielectric structure and the third horizontal portion extends along the second dielectric structure.

13. The semiconductor device of claim 9, wherein the first horizontal portion is at a level above the second horizontal portion and below the third horizontal portion.

14. The semiconductor device of claim 8, further comprising a gate electrode in contact with a top surface of the gate structure, wherein a topmost surface of the gate electrode is higher than a topmost surface of the field plate.

15. The semiconductor device of claim 8, further comprising an epitaxial layer between the donor-supply layer and the second dielectric structure, wherein the source electrode and the drain electrode extends through the epitaxial layer.

16. A method, comprising:
forming a gate structure over a channel layer;
forming a first dielectric structure covering the gate structure;
forming a source electrode and a drain electrode on opposite sides of the gate structure;
forming a field plate extending along the first dielectric structure, wherein the field plate vertically overlaps an edge of the gate structure; and
forming a gate electrode connected with the gate structure.

17. The method of claim 16, further comprising forming a second dielectric structure laterally surrounding the first dielectric structure, wherein the field plate further extends to the second dielectric structure.

18. The method of claim 16, further comprising forming a donor-supply layer over the channel layer prior to forming the gate structure.

19. The method of claim 18, further comprising:
patterning the first dielectric structure to expose portions of the donor-supply layer; and
forming an epitaxial layer over the portions of the donor-supply layer, wherein the source electrode and the drain electrode are formed extending through the epitaxial layer.

20. The method of claim 19, wherein the portions of the donor-supply layer are etched during patterning the first dielectric structure.
